(19) United States
(12) Patent Application Publication
(10) Pub. No.: US 2009/0079467 A1
(43) Pub. Date: Mar. 26, 2009

(54) METHOD AND APPARATUS FOR UPGRADING FPGA/CPLD FLASH DEVICES

(76) Inventors: Magne V. Sandven, Ski (NO); Roy Arntsen, Oslo (NO); Arne Sudgarden, Oslo (NO)

Correspondence Address: MHKKG/SUN, P.O. BOX 398, AUSTIN, TX, 78767, US

(21) Appl. No.: 11/861,830

(22) Filed: Sep. 26, 2007

(51) Int. Cl. H03K 19/173

(52) U.S. Cl. 326/38

(57) ABSTRACT

A method for programming a non-volatile memory associated with a programmable logic device (PLD). The method for programming a non-volatile memory includes a reading a data file, wherein the data file includes information to be programmed into the non-volatile memory. The data file is then translated into a plurality of commands based on the information contained therein. The plurality of command is forwarded to a microcontroller. The microcontroller then executes the plurality of commands, wherein said executing causes the non-volatile memory to be programmed.

### BACKGROUND OF THE INVENTION

1. Field of the Invention

This invention relates to electronic systems, and more particularly, to the programming/reprogramming of programmable devices within an electronic system.

2. Description of the Related Art

Programmable logic devices (PLD's) and complex PLD's (CPLD's) are used in a wide variety of electronic systems. PLD's may provide rapid prototyping and a fast time-to-market and may also allow for re-programming to fix known bugs. Thus, PLD's may provide a viable alternative to application specific integrated circuits (ASIC's) in many situations. CPLD's may be used to implement large designs having significant complexity, with gate counts numbering in the hundreds of thousands.

PLD's include programmable array logic (PAL) devices and field programmable gate arrays (FPGA's). Unlike PAL devices, FPGA's include a non-volatile memory (e.g., a flash memory) that may be implemented on the same chip as the gate array. Programming (or reprogramming) the FPGA can be accomplished by programming the non-volatile memory. During system boot-up, the information programmed on the non-volatile memory may be read by the FPGA in order to configure itself for operation.

In order to program or re-program a CPLD, a data file is generated during the design phase. This data file may then be directly written onto the non-volatile memory in order to program/re-program the CPLD. In some systems, a microcontroller performs the programming/re-programming after receiving the data file from a processor via a serial bus (e.g., a system management [SM] bus or a I²C bus).

### SUMMARY OF THE INVENTION

A method for programming a non-volatile memory associated with a programmable logic device (PLD) is disclosed. In one embodiment, a method for programming a non-volatile memory includes a reading a data file, wherein the data file includes information to be programmed into the non-volatile memory. The data file is then translated into a plurality of commands based on the information contained therein. The plurality of command is forwarded to a microcontroller. The microcontroller then executes the plurality of commands, wherein said executing causes the non-volatile memory to be programmed.

In one embodiment, a computing device includes a processor, a microcontroller, a PLD, and a non-volatile memory associated with the PLD. The processor is coupled to the microcontroller by a serial bus, such as a system management bus (SMBus) or an I²C bus. The processor is configured to read the file and convert the information therein into a plurality of commands. The commands are conveyed from the processor to the microcontroller via the serial bus. The microcontroller executes the commands in order to cause the non-volatile memory to be programmed.

A method for programming a non-volatile memory associated with a PLD in one or more remote computing devices is also contemplated. The method includes a source computer sending a data file over a network to one or more remotely located computing devices. Each of the remotely located computing devices includes a processor, a microcontroller coupled to the processor by a serial bus, a PLD, and a non-volatile memory associated with the PLD. The processor in each remotely located computing device reads the data file and translates it into a plurality of commands. The plurality of commands is sent by each processor to its corresponding microcontroller via the corresponding serial bus. Each microcontroller executes the received plurality of commands in order to program its corresponding non-volatile memory.

### BRIEF DESCRIPTION OF THE DRAWINGS

Other aspects of the invention will become apparent upon reading the following detailed description and upon reference to the accompanying drawings in which:

FIG. 1 is a block diagram of one embodiment of a computing device having a programmable logic device (PLD) and an associated non-volatile memory;

FIG. 2 is a flow diagram of one embodiment of a method for programming a non-volatile memory associated with a PLD by using a protocol to translate a data file into a plurality of commands;

FIG. 3A is portion of a flow diagram illustrating one embodiment of a programming procedure performed translating a data file and executing a plurality of commands created from the data file;

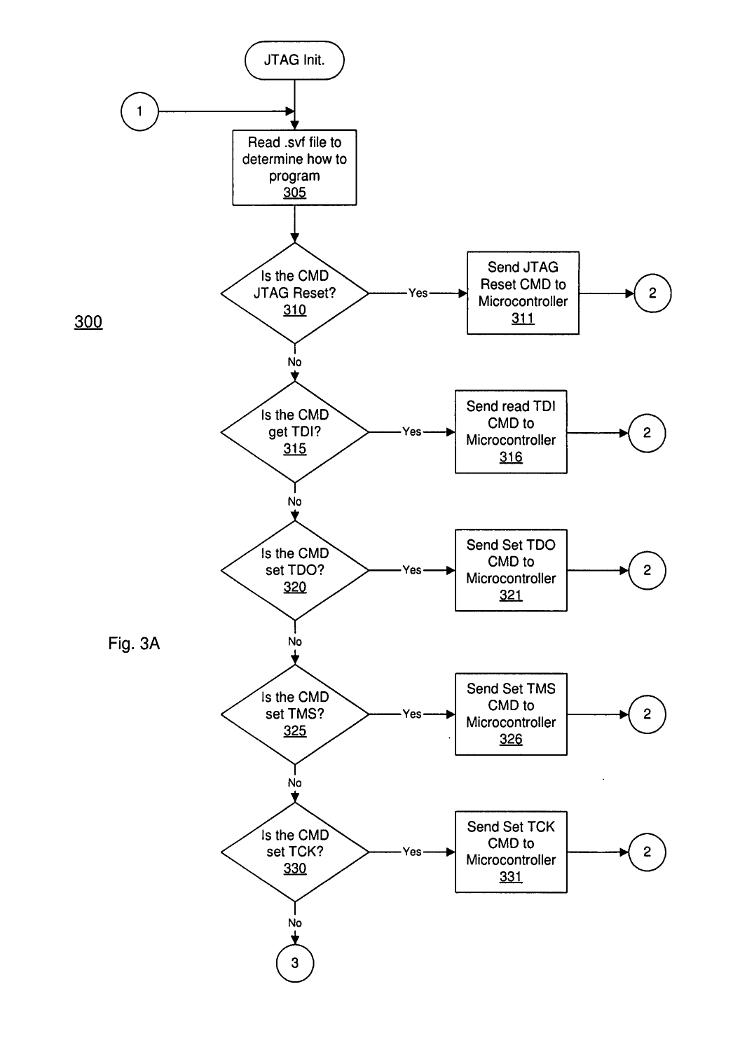

FIG. 3B is another portion of the flow diagram illustrating one embodiment of a programming procedure performed translating a data file and executing a plurality of commands created from the data file; and

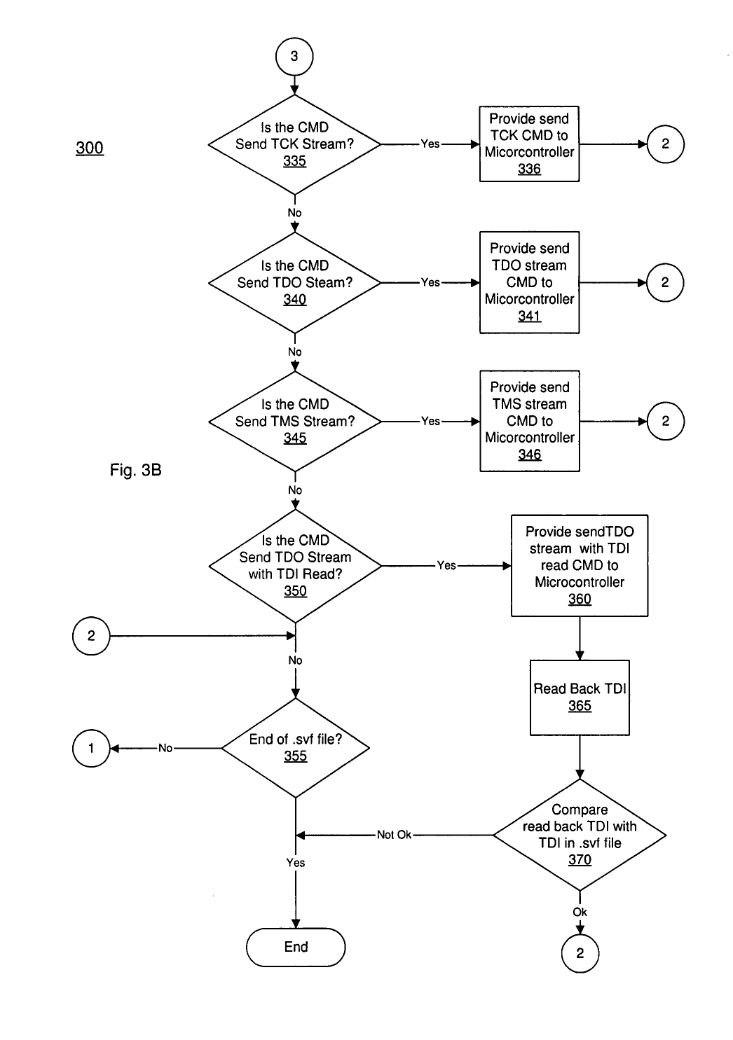

FIG. 4 is a block diagram of one embodiment of a network wherein a source computer is capable of causing the programming of a flash memory associated with a PLD in one or more remotely located computing devices.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling with the spirit and scope of the present invention as defined by the appended claims.

### DETAILED DESCRIPTION OF THE INVENTION

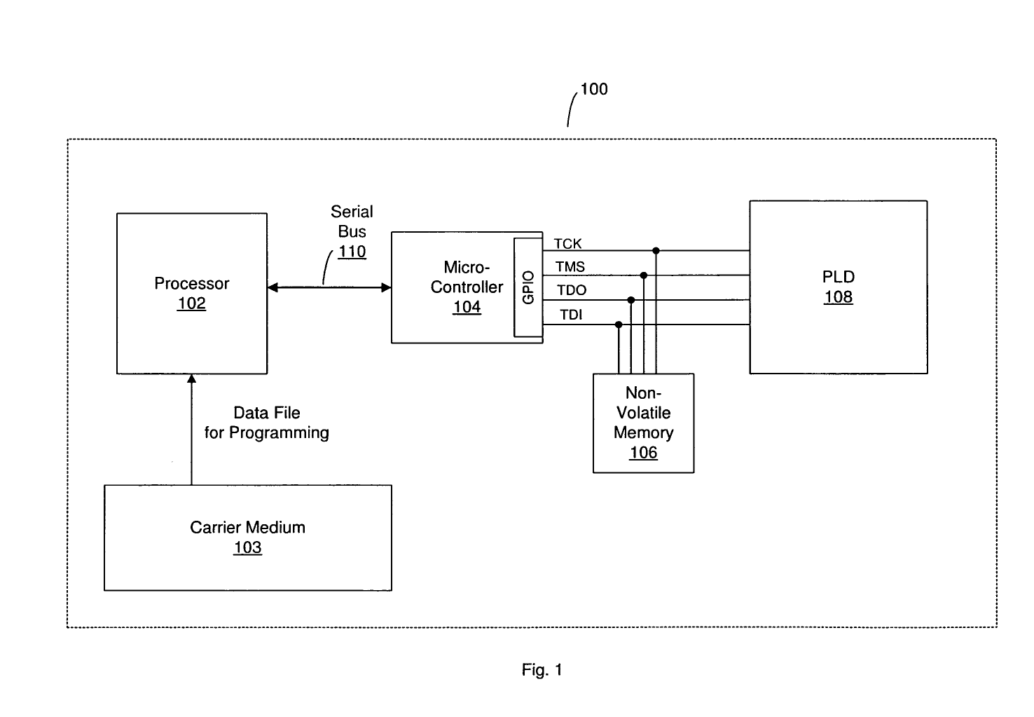

Turning now to FIG. 1, a block diagram of one embodiment of a computing device having a programmable logic device (PLD) and an associated non-volatile memory. As used herein, the term ‘computing device’ may refer to a wide variety of computers and/or computer related equipment. For example, a computing device may be a personal computer, a computer terminal coupled to a mainframe computer or a blade server, various types of network equipment such as routers, hubs, and switches, and other types of electronic equipment. In general, the term ‘computing device’ as used herein may refer to any type of electronic equipment that includes a processor, a microcontroller, a PLD, and an associated non-volatile memory in an arrangement similar or equivalent to that shown in FIG. 1.

In the embodiment shown, computing device 100 includes a processor 102 coupled to a microcontroller 104. In some embodiments, processor 102 may be a general-purpose microprocessor (e.g., a processor that utilizes the x86 or other type of general-purpose instruction set architecture). In other embodiments, processor 102 may be a specialized processing device (e.g., an application specific integrated circuit, or ASIC) designed to perform one or more specific processing functions. Microcontroller 104 may be any type of microcontroller suitable for use with computing device 100.

Processor 102 is coupled to microcontroller 104 by a serial bus 110. In one embodiment, the serial bus may be a system management bus (SMBus) that conforms to a version of the SMBus standard introduced by Intel Corporation in 1996. In another embodiment, serial bus 110 may be an inter-integrated circuit (or I²C) bus. In general, serial bus 110 may be any type of serial bus that is used in a computing device to allow communications between a processor and a microcontroller.

Computing device 100 also include PLD 108. In the embodiment shown, PLD 108 is a complex PLD (CPLD) that is associated with the non-volatile memory 106. Programming (which may include re-programming) the PLD may be performed by writing data into non-volatile memory 106. In one embodiment, the PLD is a field programmable gate array (FPGA), while the non-volatile memory is a flash memory. Embodiments wherein a static random access memory (SRAM) are used in lieu of a flash memory are also possible and contemplated. Other types of complex PLD's (other than FPGA's) that utilize a non-volatile memory are also possible and contemplated for various embodiments.

In the embodiment shown, microcontroller 104 includes a general purpose I/O (GPIO) port that includes a JTAG (Joint Test Action Group, the IEEE 1149.1 standard) port. During programming operations, communications between microcontroller 104, non-volatile memory 106, and PLD 108 are conducted over the JTAG connections, which include a test clock (TCK) connection, a test mode select (TMS) connection, a test data in (TDI) connection, and a test data out (TDO) connection. Because of the versatility of the JTAG standard, it may be particularly suitable for programming non-volatile memory 106. However, the JTAG standard used here represents one possible embodiment, as other types of communications protocols may be used in other embodiments.

In the embodiment shown, computing device 100 includes a carrier medium 103. Among other things, carrier medium 103 may store a data file used to program the non-volatile memory. Also stored on carrier medium 103 may be instructions that, when executed by processor 102, cause the information contained in the data file into a plurality of commands that can be conveyed to microcontroller 104 in order to effect the programming of non-volatile memory 106. This method of programming will be discussed in further detail below.

Carrier medium 103 may be one or more of several different types of storage mediums. For example, carrier medium may be a CD-ROM, a data DVD, a floppy disk, a flash drive, or hard disk drive (either portable or implemented within computing system 100). Carrier medium 103 may also include on-board RAM or ROM as well. Since carrier medium may include multiple storage types. For example, the data file used for programming non-volatile memory 106 may be stored on a data DVD, while the instructions for translating the data file into a plurality of commands may be stored on a hard drive. In general, carrier medium 103 as shown in FIG. 1 may incorporate all of the different types of storage mediums that may be used in computing device 100.

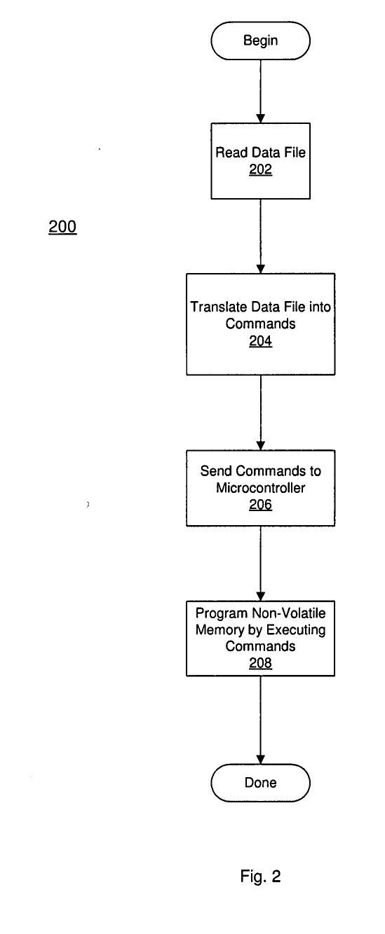

FIG. 2 is a flow diagram of one embodiment of a method for programming a non-volatile memory associated with a PLD by using a protocol to translate a data file into a plurality of commands. The method may be particularly useful for configurations alike or similar to that of computing device 100 in FIG. 1. More particularly, the method described herein may avoid the need to transfer the data file across the serial bus to microcontroller. Instead, the method may transfer commands (and associated argument(s), if applicable) to the microcontroller, which may result in a significant reduction in the amount of time necessary to program the non-volatile memory. The method will be explained in reference to the configuration shown in FIG. 1.

Method 200 begins with the reading of a data file (202). The data file, which contains the information necessary to program non-volatile memory 106, is read by processor 102 from a carrier medium 103. Processor 102 may execute instructions that allow information in the data file to be translated into commands (204), i.e. commands are generated from the information in the data file. This may occur after processor has read the data file, or concurrently with the reading of the data file. The commands may conform to a protocol, and some commands may require arguments. After the commands are generated, they may be sent to microcontroller 104 via serial bus 110 (206). As (or after) microcontroller 104 receives the commands, it can then execute the commands in order to cause the non-volatile memory to be programmed (208).

As previously noted, sending commands (and arguments, if applicable) from processor 102 to microcontroller 104 may result in significant time savings. For example, consider a data file that may include a portion having 100,000 consecutive logic 1's to be written into non-volatile memory 106. Rather than processor 102 sending 100,000 consecutive logic 1's over the serial bus (which may consume a significant amount of time), a command may be generate that instructs the microcontroller to write a logic 1 to the non-volatile memory, along with an argument of 100,000, indicating the number of times the command is to be executed. Conveying the command and the argument over the serial bus consumes significantly less bandwidth than sending 100,000 consecutive logic 1's. This reduced bandwidth requirement can result in a significant time savings in a system that includes a low-bandwidth serial bus, such as one of the previously mentioned bus types (i.e. SMBus, I²C bus).

Translation of the data file in order to generate commands is based on a pre-defined protocol. Thus, the instructions executed by processor 102 when translating the data file into commands results in a plurality of commands according to the protocol. The protocol defines which commands are generated from the translation of the data file, and what arguments are applied. Table 1 below illustrates one example of a plurality of different commands that may be generated according to a pre-defined protocol. In this particular example, the commands instruct the microcontroller to perform various actions on the JTAG pins that couple microcontroller 104, non-volatile memory 106, and PLD 108. Other embodiments based on interfaces different from the JTAG interface are possible and contemplated. Furthermore, embodiments implementing additional commands other than those shown here are also possible and contemplated.

```
TABLE 1
jtag_init( ): configure TDO, TCK, and TMS as outputs and set the pin
    level to 0.
jtag_reset( ): set all outputs to level 0 and configure TDO, TCK, and
    TMS as inputs.
get_tdi( ): returns the value on the TDI pin.
```

| | |
|---|---|
| set_tdo (level 0/1): | set the TDO pin to level 0 or 1 (depending on the |
| argument). | |
| set_tms(level 0/1): | set the TMS pin to level 0 or 1 (depending on the |
| argument). | |
| set_tck(level 0/1): | set the TCK pin to level 0 or 1 (depending on the |
| argument). | |

send_tck_stream(num): toggle the TCK pin num times,
wherein num is the input argument.

| | |
|---|---|
| send_tms_stream (bit_vector, num, tms): | toggle TMS and TCK pins |

```
    according to input bit_vector, wherein num is the number of bits in
    the bit_vector
```

| | |
|---|---|
| send_tdo_stream (bit_vector, num, tms): | toggle TDO and TCK pins |

```
    according to input bit_vector, wherein num is the number of bits in
    the bit_vector. When the last TDO is to be clocked out, the TMS
    pin is set to the value given by the input parameter TMS.
Send_tdo_read_tdi_stream(bit_vector, num, tms): as
    send_tdo_stream, but on every clock cycle, this function reads the
    TDI pin and
    returns it in a bit_vector.
```

FIG.'s 3A and 3B are flow diagrams illustrating one embodiment of a programming procedure performed by translating a data file and executing commands created from the data file. The commands generated in this particular example are generated from a .svf (serial vector format) file, and are based on the exemplary protocol shown above in Table 1. Embodiments using data file formats and different protocols are also possible and contemplated.

In the embodiment shown, the programming procedure (method 300) begins with the execution by the microcontroller of the jtag_init() command, which configures the TDI, TDO, TMS, and TCK pins of the microcontroller as outputs and sets their respective logic levels to logic 0. After this command has been executed (or concurrently with the command's execution), the processor begins reading the .svf file to determine how to program the non-volatile memory associated with the PLD (305). For each portion of the file read, the processor conducts one or more checks to determine if the portion translates into one of the commands according to the protocol. If the portion read translates into a command, the command is sent to the microcontroller, where it can be executed by the microcontroller as part of the programming of the non-volatile memory. For example, if the portion of the data file read by the processor translates into a jtag_reset command (310, yes), the processor sends the jtag_reset command to the microcontroller (311). After sending the jtag_reset command to the microcontroller, the processor checks to see if it has read to the end of the .svf file (355). If the .svf file has not been fully read (355, no), then the method returns to read the next portion of the .svf file (305).

The method will continue this cycle until the .svf file has been fully read. For each cycle, it will read a portion of the file. After reading the portion of the file, the processor conducts one or more check to see which command (if any) the read portion translates into. For some commands (e.g., the send TCK stream command) the processor may also determine the correct argument to be sent with the command to the microcontroller.

In the case where the portion of the file read translates into the send_tdo_read_tdi_stream command (350, yes), the command (and required arguments) are sent to the microcontroller (360). For each clock cycle in which this command is executed the state of the TDI pin is read back by the processor (365). As the TDI pin is read back, it is compared with data in the .svf file that indicates the desired state of the TDI pin. A comparison is conducted to determine if the data read from the TDI pin matches the data indicated by the .svf file. If the comparison is ok (370, Ok), the method then conducts another check to determine if the .svf file has been fully read (355). If the comparison is not ok (370, Not Ok), the method ends, and the programming is unsuccessful. Another attempt to program the non-volatile memory can be made if desired.

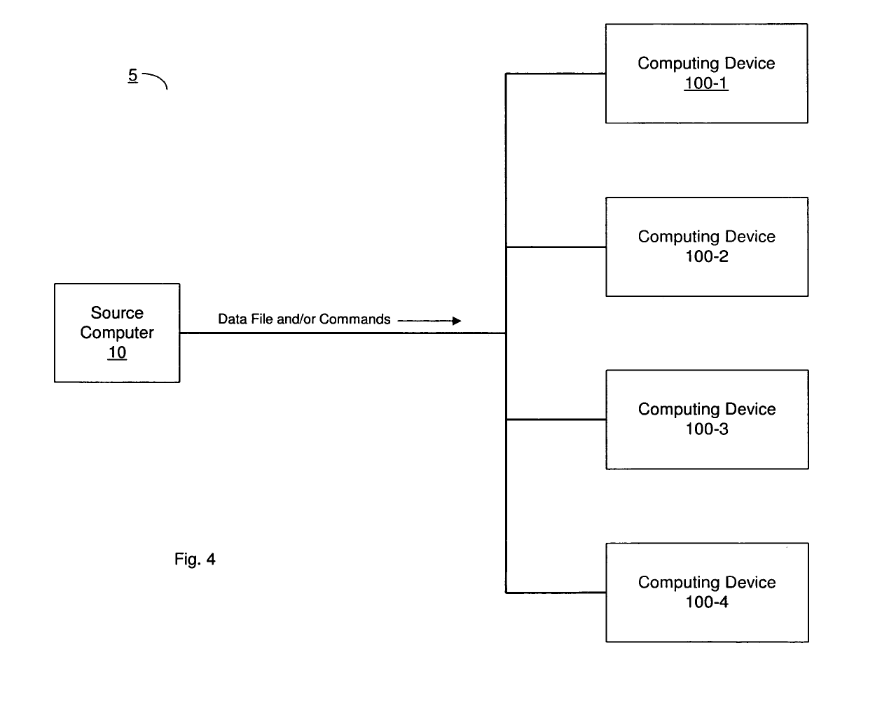

FIG. 4 is a block diagram of one embodiment of a network wherein a source computer is capable of causing the programming of a flash memory associated with a PLD in one or more remotely located computing devices. Network 5 includes a source computer 10 and a plurality of computing devices 100 (e.g., 100-1, 100-2, and so forth). Computing devices 100 may include a variety of different devices, such as computers attached to the network, terminals coupled to mainframe computers or blade servers, switches, routers, hubs, and so forth. Additional computing devices may also be present. The computing devices 100 are remotely located with respect to source computer 100. As used herein, the term remotely can refer to another computing device connected through network 5 to source computer in close proximity, thousands of miles distant, or anywhere in between. For example, network 5 may be an enterprise-wide network that includes other computing devices in the same building as source computer 10, as well as devices that are hundreds or thousands of miles away, and possible even on different continents than source computer 10. The types of networks encompassed by network 5 may include the internet, wide area networks (WANs), local area networks (LANs), wireless local area networks (WLANs), and so forth. It should also be noted that network 5 may encompass more than one of these types of networks (e.g., may include a LAN coupled to the internet, etc.).

Each of computing devices 100 may include a processor, a microcontroller, a PLD, and a non-volatile memory in a configuration alike or similar to that shown in FIG. 1. Source computer 100 is configured to send a data file (e.g., an .svf file) to one or more of the computing devices 100 should it be necessary or desirable update their corresponding non-volatile memories with new programming. Source computer 10 may also send commands to the corresponding computing devices 100 in order to initiate the programming of the non-volatile memory for each one that receives the data file. Each computing device 100 receiving the data file may then program the non-volatile memory in accordance with an embodiment of the method described above.

Alternatively, programming of the non-volatile memories can be performed by sending commands according to the protocol over the network. Instead of conveying the data file to each of computing devices 100, a method is contemplated wherein a processor in source computer 10 reads the information in a data file and generates commands according to a pre-defined protocol (such as the one discussed above) by translating the information. The commands generated from translating the information in the data file are then conveyed over the network to those computing devices 100 which each have a PLD-associated non-volatile memory to be updated. Each computing device 100 subject to the update receives the commands and executes them on a corresponding microcontroller. By executing the commands, the microcontroller programs the corresponding non-volatile memory. Utilizing this method may allow all of the translation/command generation to be performed on a single computer (i.e. the source computer) while preserving processing bandwidth for the processors on the computing devices 100 that are subject to the update. The method may also be useful in embodiments wherein the processors of the computing devices 100 are unable to translate the information into commands (e.g., the computing device does not include a carrier medium storing instructions that can be executed by the processor in order to translate the commands), or wherein one or more of the computing devices 100 do not include a processor capable of translating the commands.

Thus, using one of the above-described methods, source computer 10 can initiate the programming/re-programming of a non-volatile memory associated with a PLD for one or more remote computer devices 100 coupled thereto by a network. For example, an internet service provider could reprogram a flash memory associated with a PLD in a number of network switches, doing so remotely from a central location without the need for on-site technicians at each of the switch locations. Furthermore, utilizing the method described above, wherein the data file is used to generate commands that are transferred to the microcontroller of a devices to be updated (instead of transferring the data file itself to the microcontroller), the programming/reprogramming may be accomplished in a significantly shorter time period, thereby minimizing the down time of the computing device that is having the flash/FPGA (or other non-volatile memory/PLD) updated.

While the present invention has been described with reference to particular embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

What is claimed is:

1. A method for programming a non-volatile memory associated with a programmable logic device (PLD), the method comprising:
reading a data file, wherein the data file includes information to be programmed into the non-volatile memory;
translating the data file into a plurality of commands based on the information;
forwarding the plurality of commands to a microcontroller; and
executing each of the plurality of commands, wherein said executing causes the non-volatile memory to be programmed, wherein said executing is performed by the microcontroller.

2. The method as recited in claim 1, wherein said reading is performed by a processor, wherein the processor is coupled to the microcontroller by a serial bus.

3. The method as recited in claim 2, wherein the serial bus is a system management bus (SMBus).

4. The method as recited in claim 2, wherein the serial bus is an I²C bus.

5. The method as recited in claim 1, wherein the non-volatile memory is a flash memory.

6. The method as recited in claim 1, wherein the non-volatile memory is a static random access memory (SRAM).

7. The method as recited in claim 1, wherein the data file is a serial vector format (.svf) file.

8. The method as recited in claim 1, wherein the PLD is a field programmable gate array (FPGA).

9. A system comprising:
a processor, wherein the processor is configured to read a data file and translate information in the data file into a plurality of commands;
a microcontroller coupled to receive the plurality of commands from the processor;
a programmable logic device PLD; and
a non-volatile memory associated with the PLD;
wherein the microcontroller is configured to execute each of the plurality of commands, wherein executing the plurality of commands causes the non-volatile memory to be programmed.

10. The system as recited in claim 9, wherein the microcontroller is coupled to the processor by a serial bus.

11. The system as recited in claim 10, wherein the serial bus is a system management bus (SMBus).

12. The system as recited in claim 10, wherein the serial bus is an I²C bus.

13. The system as recited in claim 9, wherein the non-volatile memory is a flash memory.

14. The system as recited in claim 9, wherein the non-volatile memory is a static random access memory (SRAM).

15. The system as recited in claim 9, wherein the data file is a serial vector format (.svf) file.

16. The system as recited in claim 9, wherein the PLD is a field programmable gate array.

17. A method for updating a non-volatile memory associated with a programmable logic device (PLD) in a computing device coupled to a network, the method comprising:
reading a data file on a source computer, wherein the data file includes information to be programmed into the non-volatile memory of each of the one or more computing devices;
translating the data file into a plurality of commands based on information in the data file, wherein said translating is performed by a processor of the source computer;
sending each of the plurality of commands over the network to the computing device, wherein the computing device is remotely located with respect to the source computer; and
executing each of the plurality of commands, wherein said executing causes the non-volatile memory associated with the PLD to be programmed, and wherein said executing is performed by a microcontroller in the computing device.

18. The method as recited in claim 17 further comprising:
sending each of the plurality of commands over the network to a plurality of computing devices, wherein each of the plurality of computing devices is remotely located with respect to the source computer; and
a microcontroller in each of the plurality of computing devices executing each of the plurality of commands, thereby causing a corresponding non-volatile memory associated with a corresponding PLD to be updated.

19. The method as recited in claim 17, wherein the non-volatile memory is a flash memory.

20. The method as recited in claim 17, wherein the PLD is a field programmable gate array (FPGA).
